(19) United States
(12) Patent Application Publication
(10) Pub. No.: US 2012/0291863 A1
(43) Pub. Date: Nov. 22, 2012

(54) SOLAR CELL AND MANUFACTURING METHOD THEREOF

(76) Inventors: Dong-Chul SUH, Suwon-si (KR); Kyoung-Jin Seo, Yongin-si (KR); Hyun-Jong Kim, Yongin-si (KR); Byong-Gook Jeong, Yongin-si (KR); June-Hyuk Jung, Yongin-si (KR)

(21) Appl. No.: 13/424,674

(22) Filed: Mar. 20, 2012

(30) Foreign Application Priority Data
May 19, 2011 (KR) 10-2011-0047426

(51) Int. Cl. H01L 31/0216; H01L 31/0236; C23C 16/455; H01L 31/18

(52) U.S. Cl. 136/256; 438/98; 136/252; 118/719; 257/E31.124

(57) ABSTRACT

A solar cell includes a base substrate including a first surface and a second surface opposite the first surface, the base substrate being configured to have sunlight incident on the first surface, a doping layer on the first surface of the base substrate, a first passivation layer on the doping layer, the first passivation layer including hydrogen, a first capping layer on the first passivation layer, the first capping layer being configured to prevent discharge of hydrogen from the first passivation layer, a first electrode on the first capping layer, and a second electrode on the second surface of the base substrate.

### BACKGROUND

1. Field

The described technology relates generally to a solar cell and a manufacturing method thereof. More particularly, the described technology relates generally to a solar cell with a double-sided passivation configuration and a manufacturing method thereof.

2. Description of the Related Art

A solar cell represents an energy transforming device for converting sunlight energy into electrical energy by applying a photovoltaic effect. The solar cell generates electrons and holes when light is incident on a surface of a substrate, and the generated charges move to a first electrode and a second electrode to generate a photoelectromotive force that is a potential difference between the first electrode and the second electrode. In this instance, when a load is connected to the solar cell, a current flows.

The above information disclosed in this Background section is only for enhancement of understanding of the background of the described technology and therefore it may contain information that does not form the prior art that is already known in this country to a person of ordinary skill in the art.

### SUMMARY

The described technology has been made in an effort to provide a solar cell with a simplified manufacturing process and reduced production costs.

An exemplary embodiment provides a solar cell, including a base substrate including a first surface and a second surface opposite the first surface, the base substrate being configured to have sunlight incident on the first surface, a doping layer on the first surface of the base substrate, a first passivation layer on the doping layer, the first passivation layer including hydrogen, a first capping layer on the first passivation layer, the first capping layer being configured to prevent discharge of hydrogen from the first passivation layer, a first electrode on the first capping layer, and a second electrode on the second surface of the base substrate. The first passivation layer may include at least one of silicon nitride (SiNₓ), silicon oxide (SiOₓ), and silicon oxynitride (SiON).

The first capping layer may include at least one of silicon nitride (SiNₓ), silicon oxynitride (SiON), aluminum nitride (AlN), aluminum oxide (AlOₓ), a carbon thin film, cerium oxide (CeOₓ), and titanium oxide (TiOₓ).

The first capping layer may have a thickness of about 5 nm to about 30 nm.

The solar cell may further include a second passivation layer on the second surface of the base substrate, and a second capping layer on the second passivation layer, the second electrode being on the second capping layer.

The solar cell may further include a back surface field (BSF) layer on the second surface of the base substrate, the BSG layer including aluminum (Al) paste, and the second electrode being on the BSF layer.

An exemplary embodiment also provides a solar cell, including a base substrate including a first surface and a second surface opposite the first surface, the base substrate being configured to have sunlight incident on the first surface, a doping layer on the first surface of the base substrate, first and second passivation layers on the doping layer and on the second surface of the base substrate, respectively, each of the first and second passivation layers including a negative charge oxide film, first and second capping layers on respective first and second passivation layers, and first and second electrodes on respective first and second capping layers.

The first and second passivation layers may include aluminum oxide (AlOₓ).

The first and second capping layers may include silicon nitride (SiNₓ).

An exemplary embodiment also provides a method for manufacturing a solar cell, including forming a doping layer on a first surface of a base substrate, such that sunlight is incident on the first surface, forming a first passivation layer on the doping layer, the first passivation layer including hydrogen, forming a first capping layer on the first passivation layer, such that the first capping layer is configured to prevent discharge of hydrogen from the first passivation layer, forming a first electrode on the first capping layer, and forming a second electrode on a second surface of the base substrate, the second surface being opposite the first surface.

Forming the first passivation layer may include performing a plasma enhanced chemical vapor deposition method.

The method may further include forming a second passivation layer on the second surface of the base substrate, and forming a second capping layer on the second passivation layer.

The first capping layer and the second passivation layer may be formed simultaneously of the same material.

Forming the first capping layer on the first passivation layer and forming the second passivation layer on the second surface of the base substrate may include providing the base substrate to a loader, providing the base substrate to a first processor connected to a first buffer, after passing through the first buffer connected to the loader, depositing the second passivation layer on the second surface of the base substrate by the first processor, depositing the first capping layer on the first passivation layer by a second processor adjacent the first processor, providing the base substrate to an unloader by passing the same through a second buffer connected to the second processor, and detaching the base substrate by the unloader.

The first and second processors may be formed in respective first and second chambers, the first and second chambers being formed to be connected with each other in an open gate form or being formed in a single chamber.

The method may further include forming a back surface field layer on the second surface of the base substrate, forming the back surface field layer on the second surface of the base substrate including forming an aluminum paste on the second surface of the base substrate, and applying heat to the aluminum paste, such that aluminum diffuses to the second surface of the base substrate.

An exemplary embodiment also provides a method for manufacturing a solar cell, including forming a doping layer on a first surface of a base substrate, such that sunlight is incident on the first surface, and the second surface is opposite the first surface, forming first and second passivation layers on the doping layer and on the second surface of the base substrate, respectively, each of the first and second passivation layers including a negative charge oxide film, forming first and second capping layers on the first and second passivation layers, respectively, and forming first and second electrodes on the first and second capping layers, respectively.

Forming the first and second passivation layers may be performed simultaneously, and forming the first and second capping layers may be performed simultaneously.

Forming the first and second capping layers may include performing a low pressure chemical vapor deposition method.

Forming the first and second passivation layers may include providing the base substrate to a loader, providing the base substrate to a first processor connected to a first buffer, after passing through the first buffer connected to the loader, depositing the first passivation layer on the doping layer of the base substrate by the first processor, depositing the second passivation layer on the second surface of the base substrate by a second processor adjacent the first processor, providing the base substrate to an unloader after passing through a second buffer connected to the second processor, and detaching the base substrate by the unloader.

Forming the first and second capping layers may include providing the base substrate to the loader, providing the base substrate to the first processor after passing through the first buffer, forming the first capping layer on the first passivation layer of the base substrate by the first processor, depositing the second capping layer on the second passivation layer of the base substrate by the second processor, providing the base substrate to the unloader after passing through the second buffer, and detaching the base substrate by the unloader.

The first and second processors may be formed in respective first and second chambers, the first and second chambers being formed to be connected with each other in an open gate form or being formed in a single chamber.

An exemplary embodiment also provides a deposition device, including a loader configured to load a wafer having a first surface and a second surface opposite the first surface, the wafer having a doping layer on the first surface, a first buffer connected to the loader and configured to move the wafer, a first processor connected to the first buffer and configured to deposit a material on the first surface of the wafer, a second processor adjacent the first processor and configured to deposit a material on the second surface of the wafer, a second buffer connected to the second processor and configured to move the wafer, and an unloader connected to the second buffer and configured to unload the wafer.

The first processor and the second processor may be configured to deposit the material without standing-by exposure.

The first and second processors may be configured to deposit dielectric on the first and second surfaces, the dielectric layers being capping layers including aluminum oxide (AlOₓ), aluminum nitride (AlN), silicon oxide (SiOₓ), silicon nitride (SiNₓ), or silicon oxynitride (SiON), and/or being passivation layers including silicon nitride (SiNₓ), carbon thin films, aluminum nitride (AlN), silicon oxynitride (SiON), silicon carbide (SiC), or silicon carbonitride (SiCN).

The first processor may be in a first chamber, the second processor may be in a second chamber, and a surface of the first chamber and a surface of the second chamber may be connected with each other in an open gate form.

The first processor and the second processor may be in a same chamber.

### BRIEF DESCRIPTION OF THE DRAWINGS

Features and advantages will become more apparent to those of ordinary skill in the art by describing in detail exemplary embodiments with reference to the attached drawings, in which:

FIG. 1 illustrates a perspective view of a solar cell according to an exemplary embodiment.

FIG. 2 illustrates a cross-sectional view of FIG. 1 along line I-I′.

FIG. 3 illustrates a graph of reflectivity with respect to wavelength in a double antireflection film with different refractive indexes according to exemplary embodiments.

FIG. 4 illustrates a graph comparing lifetime of a solar cell with a capping layer on both surfaces thereof and lifetime of a solar cell without a capping layer.

FIG. 5A to FIG. 5G illustrate cross-sectional views of stages in a method for manufacturing a solar cell according to an exemplary embodiment.

FIG. 6 illustrates a perspective view of a deposition device for depositing a passivation layer and a capping layer of a solar cell according to an exemplary embodiment.

FIG. 7 illustrates a cross-sectional view along lines II-II′ of FIG. 6.

FIG. 8 illustrates a perspective view of a deposition device for depositing a passivation layer and a capping layer of a solar cell according to another exemplary embodiment.

FIG. 9 illustrates a cross-sectional view along line III-III′ of FIG. 8.

FIG. 10 illustrates a perspective view of a solar cell according to another exemplary embodiment.

FIG. 11 illustrates a cross-sectional view along line IV-IV′ of FIG. 10.

FIG. 12 illustrates a perspective view of a solar cell according to another exemplary embodiment.

FIG. 13 illustrates a cross-sectional view along line V-V′ of FIG. 12.

FIG. 14A to FIG. 14B illustrate cross-sectional views of stages in a method for manufacturing a solar cell according to another exemplary embodiment.

FIG. 15 illustrates a perspective view of a solar cell according to another exemplary embodiment.

FIG. 16 illustrates a cross-sectional view along line VI-VI′ of FIG. 15.

FIG. 17A to FIG. 17E illustrate cross-sectional views of stages in a method for manufacturing a solar cell according to another embodiment.

FIG. 18 illustrates a perspective view of a solar cell according to another exemplary embodiment.

FIG. 19 illustrates a cross-sectional view along line VII-VII′ of FIG. 18.

### DETAILED DESCRIPTION

Korean Patent Application No. 10-2011-0047426, filed on May 19, 2011, in the Korean Intellectual Property Office, and entitled: “Solar Cell and Manufacturing Method Thereof,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

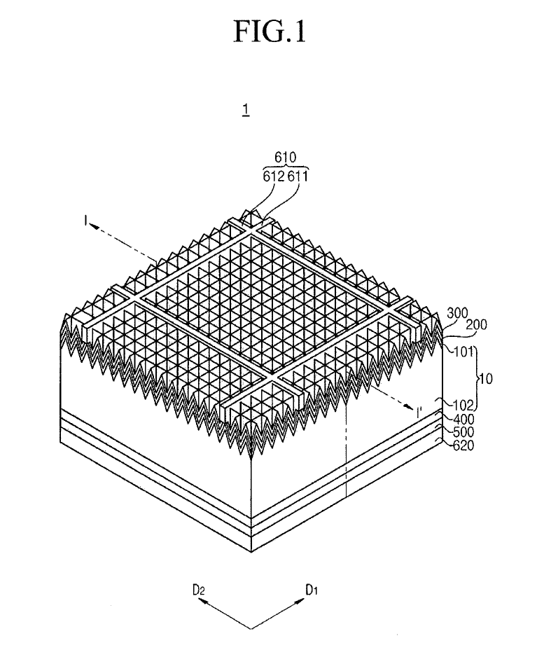

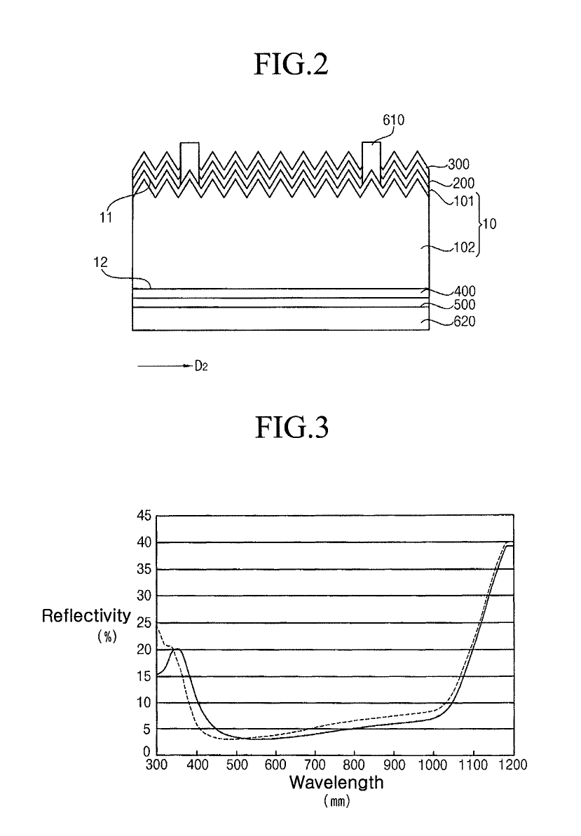

Exemplary embodiments will now be described with reference to FIGS. 1-2. FIG. 1 shows a perspective view of a solar cell according to an exemplary embodiment, and FIG. 2 shows a cross-sectional view along line I-I′ of FIG. 1.

Referring to FIG. 1 and FIG. 2, a solar cell 1 may include a base substrate 10, a first passivation layer 200, a first capping layer 300, a second passivation layer 400, a second capping layer 500, a first electrode 610, and a second electrode 620.

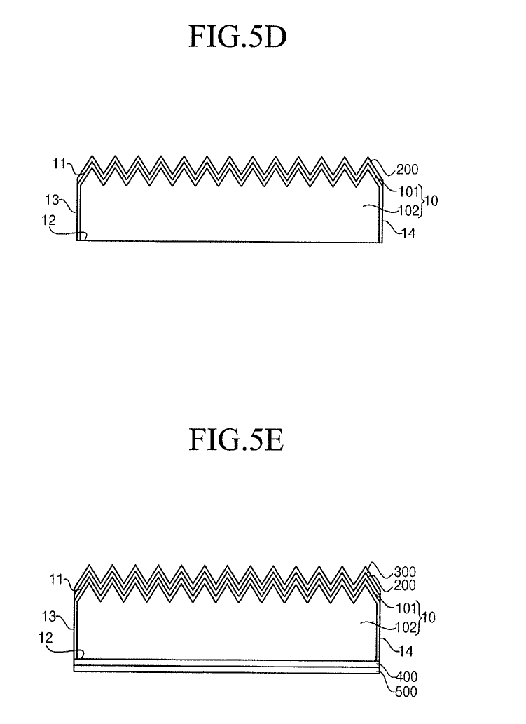

The base substrate 10 may include a first surface 11 to which sunlight is applied and a second surface 12 facing the first surface 11, i.e., the first and second surfaces 11 and 12 may be opposite each other on the substrate 10. The first surface 11 may have a protruded and depressed pattern, and the second surface 12 may be flat. The protruded and depressed pattern of the first surface 11 increases a light absorbing area and varies the light progressing direction. Therefore, a total amount of light incident on the solar cell 10 is increased, thereby increasing a number of formed electron-hole pairs (EHPs), i.e., as a result of increased light reaching area. The protruded and depressed pattern of the first surface 11 may have a pyramid shape. In this instance, the pyramid shape is not restricted to a quadrangular pyramid shape but also includes shapes having peaks and slants and it can also have a hemisphere form depending on the case. The flat, i.e., planarized, second surface 12 may be formed by wet etching a protruded and depressed pattern on the second surface 12, as will be discussed in more detail bellow with reference to FIGS. 5A-5D.

Light incident on the first surface 11 is reflected from the second surface 12, i.e., from a reflection surface, and the reflection path is simplified since the second surface 12 is flat. Therefore, light interference and dissipation within the substrate 10 may be reduced, thereby increasing an amount of light absorbed into the solar cell 1. Also, a process for forming a uniform second electrode 620 on the second surface 12 may be simplified due to the flatness of the second surface 12, as will be described in more detail below with reference to FIG. 5G.

For example, the base substrate 10 may be a p-type silicon substrate. However, other embodiments are also applicable, e.g., the base substrate 10 may be an n-type silicon substrate.

The base substrate 10 may include an n-type semiconductor layer 101 and a p-type semiconductor layer 102. The n-type semiconductor layer 101 may be formed on the first surface 11 of the base substrate 10 to contact the p-type semiconductor layer 102, and may include a dopant. For example, the dopant may include a group 5 element, e.g., phosphorous (P). The n-type semiconductor layer 101, i.e., a doping layer, may control diffusion of the dopant into the base substrate 10, i.e., into the p-type semiconductor layer 102.

As such, when external light is incident on the first surface 11 of the base substrate 10, light energy is transformed into electrical energy on a bonded surface of the p-type semiconductor layer 102 and the n-type semiconductor layer 101 of the base substrate 10, thereby generating power. The positions and number of layers of the n-type semiconductor layer 101 and the p-type semiconductor layer 102 on the substrate 10 may be variable.

The n-type semiconductor layer 101 of the base substrate 10 includes a relatively large amount of electrons, and the p-type semiconductor layer 102 includes a relatively large amount of holes. Since the n-type semiconductor layer 101 and the p-type semiconductor layer 102 contact each other, the electrons and the holes may recombine. The first passivation layer 200 according to example embodiments may control recombination of the electrons and holes in order to provide a high-efficiency solar cell 1, as will be discussed in detail below.

The first passivation layer 200 may be formed on the first surface 11, and may contact the n-type semiconductor layer 101. That is, the n-type semiconductor layer 101 and the first passivation layer 200 may be sequentially stacked on the p-type semiconductor layer 102, and the first passivation layer 200 may overlap a majority of the n-type semiconductor layer 101. The first passivation layer 200 may include an insulating material with hydrogen atoms, e.g., at least one of silicon nitride (SiNₓ) including hydrogen, silicon oxide (SiOₓ) including hydrogen, and silicon oxynitride (SiON) including hydrogen. The first passivation layer 200 may be manufactured by a plasma enhanced chemical vapor deposition (PECVD) method.

The first passivation layer 200 may control the recombination of electrons and holes in the n-type semiconductor layer 101 and the p-type semiconductor layer 102. That is, the hydrogen included in the first passivation layer 200 is combined with disconnected dangling bonds of silicon (Si) included in the base substrate 10 at the interface between the base substrate 10 and the first passivation layer 200, so that it may be difficult for the electrons and the holes to recombine. Accordingly, as recombination of electrons and holes is reduced, deterioration of light to electricity conversion efficiency of the solar cell 1 may be prevented or substantially minimized due to reduction of the front surface recombination velocity (FSRV). In other words, adjustment of an amount of hydrogen in the first passivation layer 200 may control the amount of unbonded silicon in the base substrate 10, thereby controlling the FSRV between the holes and electrons. For example, as the amount of hydrogen included in the first passivation layer 200 increases, the FSRV decreases.

The first capping layer 300 may be formed on the first passivation layer 200, e.g., the first passivation layer 200 may be formed between the first capping layer 300 and the n-type semiconductor layer 101. In detail, the hydrogen included in the first passivation layer 200 must be supplied to the base substrate 10 including the n-type semiconductor layer 101 and the p-type semiconductor layer 102. Accordingly, the first capping layer 300 prevents the hydrogen from being discharged to the outside. The first capping layer 300 may include at least one of aluminum oxide (AlOₓ), silicon oxide (SiOₓ), silicon nitride (SiNₓ), aluminum nitride (AIN), silicon carbide (SiC), cerium oxide (CeOₓ), titanium oxide (TiOₓ), and a carbon thin film. The first capping layer 300 may be formed by using the LPCVD method or a plasma chemical vapor deposition (PECVD) method. The first capping layer 300 may be formed to have a thickness of about 5 nm to about 30 nm. If the thickness of the first capping layer 300 is higher than 30 nm, insufficient sunlight may penetrate through the first capping layer 300.

The first passivation layer 200 and the first capping layer 300 may be formed as double antireflection films. That is, the first passivation layer 200 and the first capping layer 300 may be formed to have different refractive indices and may function as double antireflection films, thereby minimizing reflectivity of light incident thereon. As such, thickness of the base substrate 10 may be reduced, thereby decreasing manufacturing costs. In detail, as a silicon wafer provides a majority of the cost of a solar cell, reducing thickness of the base substrate 10 may reduce the production cost of the solar cell 1. Further, when the thickness of the base substrate 10 is reduced, in order to avoid reduced driving efficiency due to a narrow wavelength band of the light that is absorbable by the solar cell 1, the first passivation layer 200 and the first capping layer 300 may be formed as double antireflection films to minimize reflectivity of the applied light. An effect of the double antireflection films will be described later.

The second passivation layer 400 may be formed on the second surface 12 of the base substrate 10. The second passivation layer 400 may have a negative charge to push the electrons included in the p-type semiconductor layer 102. Therefore, recombination of the electrons of the n-type semiconductor layer 101 and the holes of the p-type semiconductor layer 102 may be prevented. The second passivation layer 400 may be formed of the same material as the first capping layer 300. For example, the second passivation layer 400 my include at least one of aluminum oxide (AlOₓ), silicon oxide (SiOₓ), silicon nitride (SiNₛ), aluminum nitride (AIN), silicon carbide (SiC), cerium oxide (CeOₓ), titanium oxide (TiOₓ), and a carbon thin film. The first passivation layer 400 may be formed by, e.g., LPCVD or PECVD.

The second capping layer 500 may be formed below the second passivation layer 400. That is, the second passivation layer 400 may be formed between the second capping layer 500 and the second surface 12 of the base substrate 10. The second capping layer 500 covers the second surface 12 of the solar cell 1 to prevent defects that can occur during the solar cell manufacturing process. The second capping layer 500 may include, e.g., silicon nitride (SiNₓ). The second capping layer 500 may be formed by, e.g., LPCVD or PECVD.

As illustrated in FIG. 2, the first electrode 610 may be formed on a part of the first capping layer 300 to pass through the first capping layer 300 and the first passivation layer 200 and to be electrically connected to the n-type semiconductor layer 101. As illustrated in FIG. 1, the first electrode 610 may include a plurality of bus lines 611 extended in a first direction D1 and a plurality of finger lines 612 extended in the second direction D2 substantially perpendicular to the first direction D1. The bus lines 611 may be spaced apart from each other along the second direction D2, and the finger lines 612 may be spaced apart from each other in the first direction D1.

The second electrode 620 may be formed on the second capping layer 500, e.g., may completely cover the second capping layer 500, and may be electrically connected to the p-type semiconductor layer 102. For example, the second capping layer 500 may be between the second electrode 620 and the second passivation layer 400.

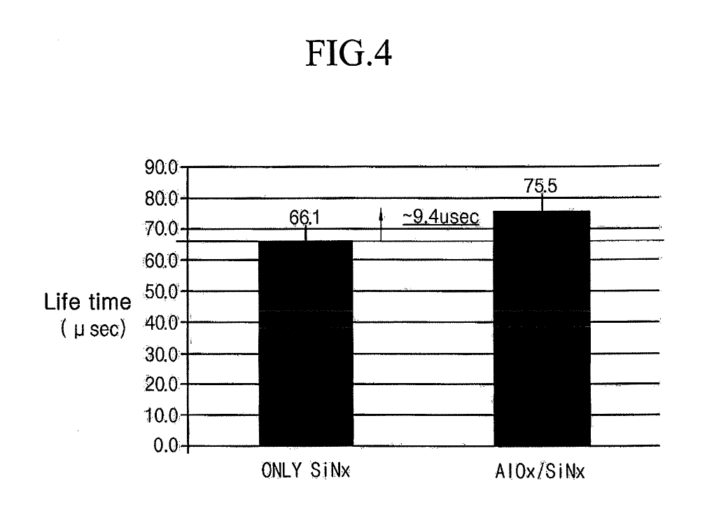

FIG. 3 shows a graph for describing reflectivity of a wavelength when a double antireflection film with different refractive indexes is formed.

Referring to FIG. 3, the illustration with a dotted line signifies inclusion of a single antireflection layer formed on the semiconductor layer, and the illustration with a solid line represents the case in which the first layer formed with silicon nitride (SiN) and the second layer formed with aluminum oxide (AlO) are included in the semiconductor layer and function as antireflection films. The a case in which an area with lower reflectivity is wider than another area when the double antireflection films are formed corresponds to the case that is shown with the solid line, that is, the case in which the antireflection films are formed with the first layer and the second layer. Therefore, when the double antireflection films are formed, the reflectivity is further reduced compared to the case in which a single antireflection film is formed.

Accordingly, the first passivation layer 200 and the first capping layer 300 function to prevent double reflection in the present exemplary embodiment. Resultantly, when the first passivation layer 200 and the first capping layer 300 are formed with materials having different refractive indices, i.e., when the first passivation layer is formed with aluminum oxide (AlOₓ) and the first capping layer 300 is formed with silicon nitride (SiNₓ), the reflectivity of the input light can be reduced.

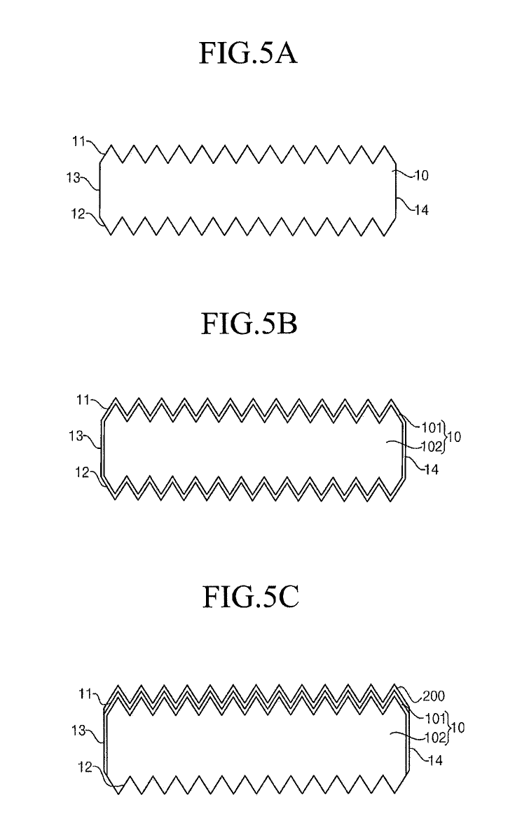

FIG. 4 shows a graph for comparing lifetimes for a case when a capping layer is formed on both surfaces of a solar cell and another case when a capping layer is not formed thereon. In this instance, the lifetime represents a time in which the electrons and the holes of the solar cell are not recombined but are maintained.

Referring to FIG. 4, a capping layer formed with aluminum oxide (Al₂O₃) on the passivation layer formed with silicon nitride (H:SiNₓ) including hydrogen is formed on both sides of the solar cell, its lifetime is 75.5 μsec. Compared to this, when the capping layer is not formed on both sides of the solar cell but the passivation layer formed with a silicon nitride (H:SiNₓ) including hydrogen is formed thereon, the lifetime is 66.1 μsec. Therefore, the lifetime when the capping layer is formed on both sides is greater than that of the other case, which means that the front surface recombination velocity (FSRV) of the top surface is reduced. Accordingly, the lifetime can be increased by forming the first capping layer 300 on the first passivation 200 including hydrogen in the present exemplary embodiment.

FIG. 5A to FIG. 5G show cross-sectional views for describing a method for manufacturing a solar cell shown in FIG. 2.

Referring to FIG. 2 and FIG. 5A, the base substrate 10 is provided by partially etching an incised surface of a p-type silicon substrate that is cut to a predetermined size. Damage occurring during a cutting process through wet etching using an acid solution can be eliminated from the base substrate 10. The base substrate 10 may include the first surface 11, the second surface 12 facing the first surface 11, a third surface 13 for connecting the first surface 11 and the second surface 12, and a fourth surface 14 facing the third surface 13. A protruded and depressed pattern may be formed on the first surface 11 and the second surface 12 of the base substrate 10. The protruded and depressed pattern may be formed on the first surface 11 and the second surface 12 by using a dipping texturing process of dipping the base substrate 10 into a solution, or an inline texturing process. The protruded and depressed pattern increases the light absorbing area and diversifies directions of the light progressing path. Therefore, the amount of input light is increased and electrode hole pairs (EHPs) that are formed at the light reaching area is increased. The protruded and depressed pattern can exemplarily have a pyramid shape, but is not limited thereto.

For convenience of description in the present exemplary embodiment, the method for manufacturing the solar cell 1 using a p-type silicon substrate is described, but an n-type silicon substrate is also usable for the base substrate 10.

Referring to FIG. 2 and FIG. 5B, a part of the base substrate 10 that is a p-type semiconductor substrate is formed as an n-type semiconductor layer 101 through a diffusion process, i.e., the n-type semiconductor layer 101 may be formed on the p-type semiconductor layer 102. In detail, phosphorous oxychloride (POCl₃) may be supplied to the base substrate 10, followed by application of heat thereto. As a result, phosphorous (P) included in the phosphorous oxychloride (POCl₃) diffuses into the surface of the base substrate 10, e.g., into the first and second surfaces 11 and 12, thereby forming the n-type semiconductor layer 101 on the surface of the base substrate 10. For example, the n-type semiconductor layer 101 may be formed on the first, second, third, and fourth surfaces 11, 12, 13, and 14 of the base substrate 10. In general, since it is not easy to remove the n-type semiconductor layer 101 from the third and fourth surfaces 13 and 14 of the base substrate 10 by etching, the n-type semiconductor layer 101 may be removed from the third and fourth surfaces 13 and 14 by a thickness of the n-type semiconductor layer 101 on the first surface 11 through a laser ablation process or laser isolation process. Therefore, the n-type semiconductor layer 101 formed on the first surface 11 may be formed to not be electrically connected to the second electrode 620. As such, a predetermined area of the base substrate 10, i.e., an area of the base substrate 10 close to the surface into which the phosphorous (P) is diffused, may be defined as the n-type semiconductor layer 101, and a different part of the base substrate 10, i.e., an area of the base substrate 10 into which phosphorous (P) is not diffused, may be defined as the p-type semiconductor layer 102. The phosphorous oxychloride (POCl₃) can be supplied as liquid or gas. The diffusion process may be performed at a temperature of about 700° C. to about 1000° C.

Although not shown, a reaction between the silicon (Si) and the phosphorous oxychloride (POCl₃) on the base substrate 10, i.e., after the diffusion process, may form a phosphorous silicate glass (PSG) layer which shields the flow of current in the solar cell 1. The PSG layer may be removed, e.g., by wet etching using hafnium (Hf), an RCA SC-1 solution, or an RCA SC-2 solution.

When the base substrate 10 is used as an n-type semiconductor, boron tri-bromide (BBr₃), rather than phosphorous oxychloride (POCl₃), may be supplied to the base substrate 10. As a result, boron diffuses into the base substrate 10 to form a p-type semiconductor layer on, e.g., to surround, the n-type semiconductor. Also, in this case, a boron-silicate glass (BSG) layer formed on the base substrate 10 may be removed by wet etching using hafnium (HF), an RCA SC-1 solution, or an RCA SC-2 solution, to prevent shielding of the current flow in the solar cell 1.

Referring to FIG. 2 and FIG. 5C, the first passivation layer 200 may be formed on, e.g., only on, the first surface 11 of the base substrate 10. The first passivation layer 200 may be formed of, e.g., silicon nitride (SiNₓ), and may include hydrogen so as to reduce the recombination speed of the electrons and the holes included by the n-type semiconductor layer 101 and the p-type semiconductor layer 102. The first passivation layer 200 may be manufactured by PECVD method. For example, ammonia (NH₃) gas and silane (SiH₄) gas may be used as source gases, to form a layer including silicon nitride and hydrogen.

Referring to FIG. 2 and FIG. 5D, the protruded and depressed pattern on the second surface 12, as well as the n-type semiconductor layer 101 on the second surface 12, may be removed through wet etching. The wet etching may be performed by exposing the base substrate 10 to an alkali solution, e.g., at least one of potassium hydroxide (KOH), sodium hydroxide (NaOH), and tetramethyl ammonium hydroxide (TMAH). In this instance, the protruded and depressed pattern on the first surface 11 is not etched because of the first passivation layer 200 on the first surface 11, i.e., the first passivation layer 200 covering the n-type semiconductor layer 101 on the first surface 11 may be used as a protection layer to prevent removal of the n-type semiconductor layer 101 from the first surface 11. Hence, after removal of the protruded and depressed pattern and the n-type semiconductor layer 101 from the second surface 12, the n-type semiconductor layer 101, i.e., a layer formed when phosphorous diffuses to a uniform distance, i.e., a constant thickness, into the first surface 11 of the base substrate 10, and the p-type semiconductor layer 102 may remain. Therefore, the n-type semiconductor layer 101 and the p-type semiconductor layer 102 may be bonded, e.g., may be in direct contact along a contact surface parallel to the first surface 11. That is, the n-type semiconductor layer 101 is formed on, e.g., defines, the first surface 11, and the p-type semiconductor layer 102 is formed on, e.g., defines, the second surface 12.

The light applied to the first surface 11 is reflected from the second surface 12 as a reflection surface, and a light reflection path is simplified since the second surface 12 is flat. Therefore, light interference may be prevented or substantially minimized, e.g., destructive light interference may be reduced, thereby increasing an amount of light absorbed by the solar cell 1.

Referring to FIG. 2 and FIG. 5E, the first capping layer 300 may be formed on the first passivation layer 200, i.e., on the first surface 11, and the second passivation layer 400 may be formed on the p-type semiconductor layer 102, i.e., on the second surface 12. The first capping layer 300 may be formed of at least one of aluminum oxide (AlOₓ), silicon oxide (SiOₓ), silicon nitride (SiNₓ), aluminum nitride (AIN), silicon carbide (SiC), cerium oxide (CeOₓ), titanium oxide (TiOₓ), and a carbon thin film. The first capping layer 300 may be formed by using LPCVD or PECVD. The first capping layer 300 may be formed to a thickness of about 5 nm to about 30 nm. The first capping layer 300 prevents the hydrogen included in the first passivation layer 200 from being discharged to the outside.

The second passivation layer 400 may be formed of the same material as the first capping layer 300. That is, the second passivation layer 400 may be formed of at least one of aluminum oxide (AlOₓ), silicon oxide (SiOₓ), silicon nitride (SiNₓ), aluminum nitride (AIN), silicon carbide (SiC), cerium oxide (CeOₓ), titanium oxide (TiOₓ), and a carbon thin film. The first capping layer 400 can be formed by using the low pressure plasma chemical vapor deposition (LPCVD) or plasma chemical vapor deposition (PECVD) method. The second passivation layer 400 may have a negative charge to have the characteristic of pushing the electrons included in the p-type semiconductor layer 102, thereby preventing recombination of the electrons included in the n-type semiconductor layer 101 and the holes included in the p-type semiconductor layer 102.

When the first capping layer 300 and the second passivation layer 400 are formed of the same material, the first capping layer 300 and the second passivation layer 400 may be formed simultaneously. For example, the first capping layer 300 and the second passivation layer 400 may be deposited by a single deposition step through sequential processes, thus simplifying the deposition process.

Referring to FIG. 2 and FIG. 5F, the second capping layer 500 may be formed on the second passivation layer 400. The second capping layer 500 may include silicon nitride (SiNₓ). The second capping layer 500 may be formed by using LPCVD or PECVD. The second capping layer 500 covers the second surface 12 of the solar cell 1 to prevent defects that can occur when the solar cell 1 is manufactured.

Referring to FIG. 2 and FIG. 5G, the first electrode 610 may be formed on a part of the first capping layer 300. In detail, a first electrode paste may be formed on a part of the first capping layer 300. The first electrode paste may include a plurality of bus lines extended in a first direction D1 and formed in a second direction D2 that is substantially perpendicular to the first direction D1, and a finger line extended in the second direction D2 and formed in the first direction D1. The first electrode paste undergoes a co-firing process to pass through the first passivation layer 200 and the first capping layer 300 and form the first electrode 610, and is then electrically connected to the n-type semiconductor layer 101.

The second electrode 620 may be formed below the second capping layer 500. Parts of the second passivation layer 400 and the second capping layer 500 are etched with laser beams, and a second electrode paste may be formed on the second capping layer 500 and the base substrate 10 that is exposed when the second passivation layer 400 and the second capping layer 500 are removed. When the formed second electrode paste undergoes a co-firing process, the second electrode 620 is formed. The second electrode 620 may be formed by melting the second electrode paste by using laser beams without performing the co-firing process and simultaneously removing the second capping layer 500 and the second passivation layer 400. Therefore, the second electrode 620 is electrically connected to the p-type semiconductor layer 102.

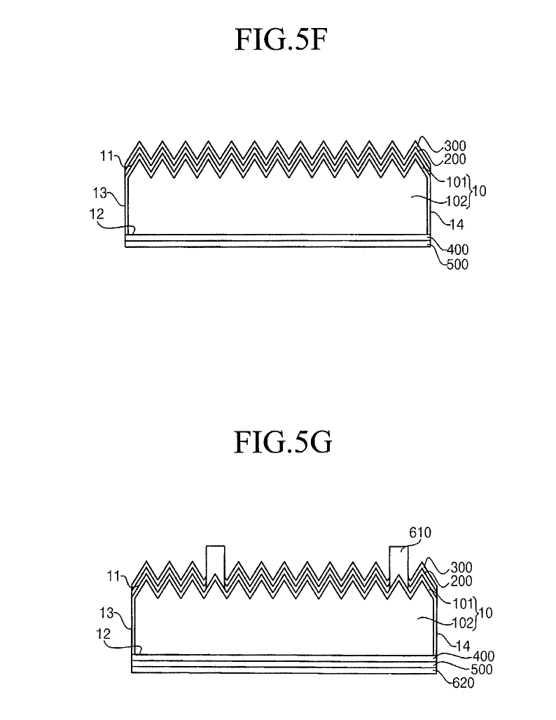

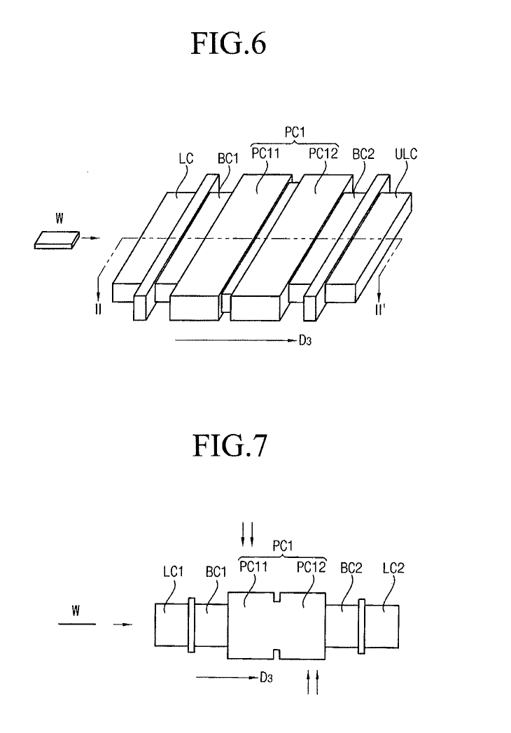

FIG. 6 shows a perspective view of a deposition device for depositing a passivation layer and a capping layer of a solar cell shown in FIG. 1. FIG. 7 shows a cross-sectional view along line II-II′ of FIG. 6.

Referring to FIG. 6 and FIG. 7, a deposition device may include an inline deposition device having a load chamber (LC), a first buffer chamber BC1, a process chamber PC1, a second buffer chamber BC2, and an unload chamber (ULC). The deposition device may deposit the passivation layers and the capping layers on both sides of the base substrate 10 included in the solar cell 1.

A wafer can be the base substrate 10, e.g., an n-type silicon wafer or a p-type silicon wafer. The base substrate 10 may include the first surface 11, the second surface 12 facing the first surface 11, the third surface 13 for connecting the first surface 11 and the second surface 12, and the fourth surface 14 facing the third surface 13. The base substrate 10 may include the n-type semiconductor layer 101 formed on the first surface 11 and the p-type semiconductor layer 102 formed on the second surface 12.

Further, the first passivation layer 200 may be formed on the first surface 11. It is also assumed that the first capping layer 300 and the second passivation layer 400 may be formed of the same material, and the base substrate 10, i.e., on which the first passivation layer 200 is formed, will be referred to as a mother substrate (W).

The mother substrate (W) moves in a third direction D3 to pass through the load chamber (LC), the first buffer chamber BC1, the process chamber PC1, the second buffer chamber BC2, and the unload chamber (ULC), so the first capping layer 300 and the second passivation layer 400 may be deposited on both sides of the mother substrate (W).

The mother substrate (W), i.e., the wafer (W), on which the first passivation layer 200 is formed, may enter the inline deposition device by the load chamber (LC). The load chamber (LC) and the process chamber (PC1) are connected through the first buffer chamber BC1. When a plurality of wafers (W) are provided, the first buffer chamber BC1 may temporarily store the wafer (W), e.g., in accordance with a process state in the process chamber PC1, so as to control the entrance time of the wafers (W) into the process chamber (PC1).

The process chamber PC1 may include a first processor PC11 and a second processor PC12. The first processor PC11 and the second processor PC12 may be formed with individual chambers. However, the sides of the first and second processors PC11 and PC12 contacting each other in the third direction D3 may be formed to be an open gate. That is, the inside of the first processor PC11 and the inside of the second processor PC12 may be open, i.e., may not be disconnected. The first processor PC11 and the second processor PC12 may supply the same material to perform a deposition process.

The first processor PC11 may perform the deposition process according to a top down sequence. That is, a plasma source inside the first processor PC11 may be formed on a top surface of the first processor PC11 to face the first surface 11 of the mother substrate (W). Therefore, when the mother substrate (W) passes through the first processor PC11, the first capping layer 300 may be deposited on the first passivation layer 200.

Also, the second processor PC12 may perform a deposition process according to a bottom up sequence. That is, the plasma source inside the second processor PC12 may be formed at the bottom surface of the second processor PC12 to face the second surface 12 of the mother substrate (W). Therefore, when the mother substrate (W) passes through the second processor PC12, the second passivation layer 400 may be deposited on the second surface 12.

The mother substrate (W) passes through the second buffer chamber BC2 to move to the unload chamber (ULC). The unload chamber (ULC) detaches the mother substrate (W) from the deposition device. Therefore, the first capping layer 300 and the second passivation layer 400 may be simultaneously formed by using the deposition device.

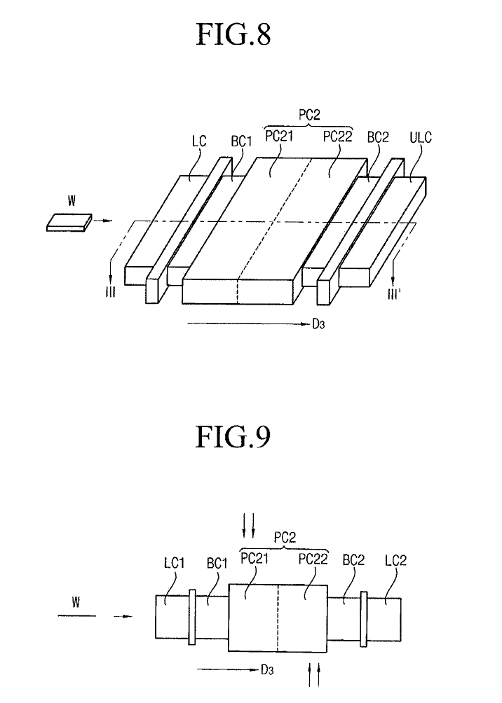

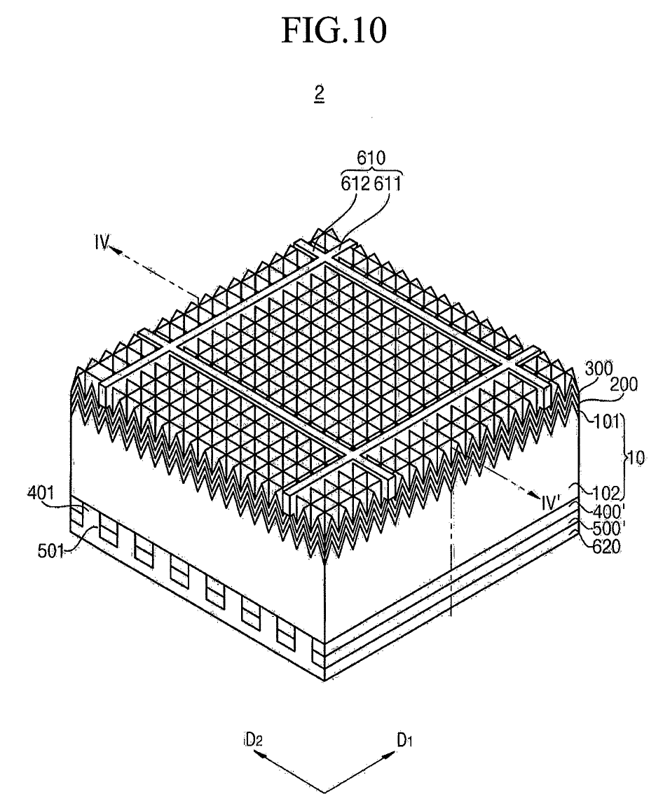

FIG. 8 shows a perspective view of a deposition device for depositing a passivation layer and a capping layer of a solar cell according to another embodiment. FIG. 9 shows a cross-sectional view along line III-III′ of FIG. 8.

It is noted that the deposition device in FIGS. 8-9 is substantially the same as the one in FIGS. 6-7 described previously, with the exception of the process chamber PC2. Referring to FIGS. 8-9, The inline deposition device may include the load chamber (LC), the first buffer chamber BC1, a process chamber PC2, the second buffer chamber BC2, and the unload chamber (ULC).

The mother substrate (W) moves in the third direction D3 to pass through the load chamber (LC), the first buffer chamber BC1, the process chamber PC2, the second buffer chamber BC2, and the unload chamber (ULC), and the first capping layer 300 and the second passivation layer 400 may be deposited on respective sides of the mother substrate (W).

The process chamber PC2 may include a first processor PC21 and a second processor PC22. The first processor PC21 and the second processor PC22 may be formed at divided areas in a single chamber. The first processor PC21 and the second processor PC22 may perform a deposition process by supplying the same material. The first processor PC21 performs a deposition process according to a top down sequence. That is, a plasma source inside the first processor PC21 may be formed on a top surface of the first processor PC11 to face the first surface 11 of the mother substrate (W). Therefore, when the mother substrate (W) passes through the first processor PC21, the first capping layer 300 may be deposited on the first passivation layer 200. Also, the second processor PC22 performs a deposition process according to a bottom up sequence. That is, the plasma source inside the second processor PC22 may be formed at the bottom surface of the second processor PC22 to face the second surface 12 of the mother substrate (W). Therefore, when the mother substrate (W) passes through the second processor PC22, the second passivation layer 400 may be deposited on the second surface 12.

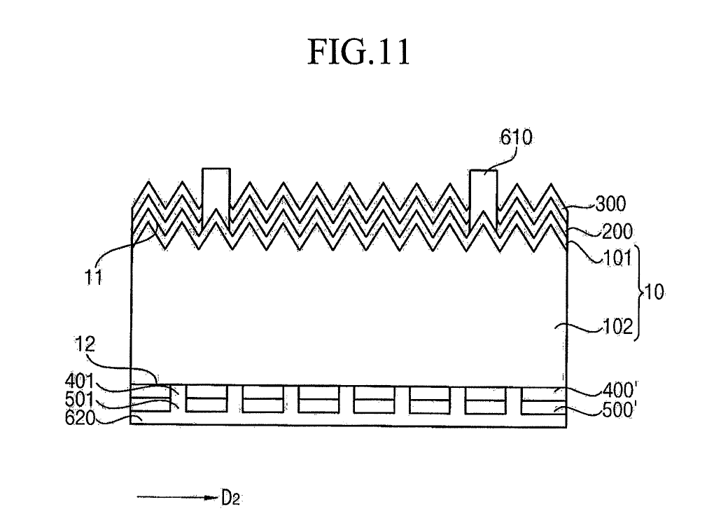

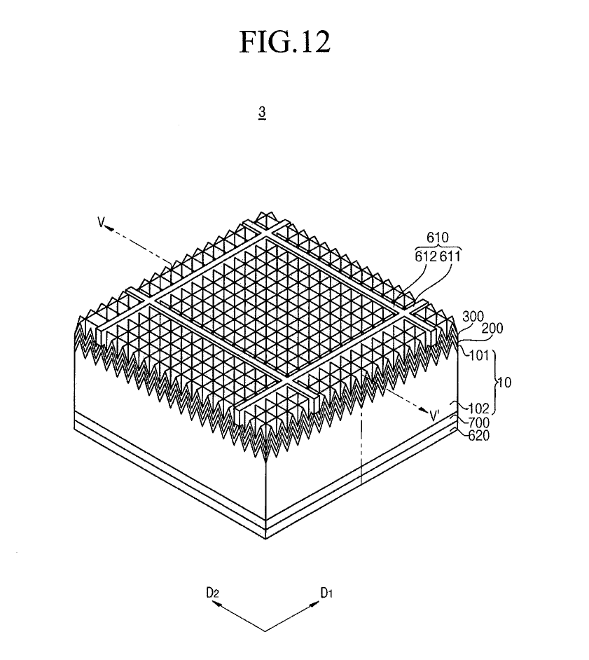

FIG. 10 shows a perspective view of a solar cell according to another exemplary embodiment. FIG. 11 shows a cross-sectional view along line IV-IV′ of FIG. 10.

Referring to FIG. 10 and FIG. 11, a solar cell 2 is substantially equivalent to the solar cell 1 of FIG. 1 and FIG. 2, except for contact holes 401 and 501 that are formed on the second passivation layer 400 and the second capping layer 500, respectively. Therefore, detailed description of same elements described previously with reference to the solar cell 1 in FIGS. 1-2 will not be repeated herein.

The solar cell 2 may include the base substrate 10, the first passivation layer 200, the first capping layer 300, the first electrode 610, the second electrode 620, a second passivation layer 400′ including the contact hole 401, and a second capping layer 500′ including the contact hole 501. For example, the contact holes 401 may overlap, e.g., completely overlap, the contact holes 501 to define a single opening. For example, each of the contact holes 401 and 501 may have a trench shape, and may extend along the direction D1 and may be spaced apart from an adjacent hole along the direction D2.

The second passivation layer 400′ and the second capping layer 500′ may be formed between the p-type semiconductor layer 102 and the second electrode 620, and may include a plurality of contact holes 401 and 501. The second electrode 620 may electrically contact the p-type semiconductor layer 102, e.g., through the openings 401 and 501.

The method for manufacturing the solar cell 2 according to the present exemplary embodiment is substantially the same as the method for manufacturing the solar cell 1 shown in FIG. 2. The contact holes 401 and 501 may be formed on the second passivation layer 400 and the second capping layer 500, respectively, by using a laser edge paste or photolithography.

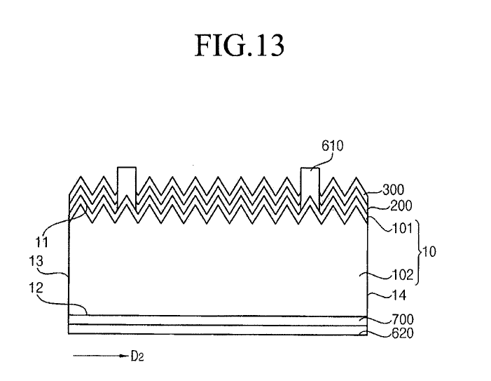

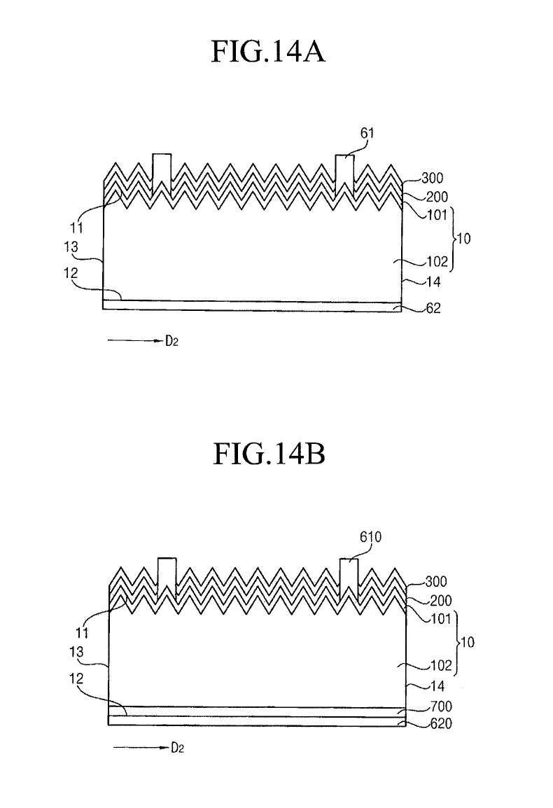

FIG. 12 shows a perspective view of a solar cell according to another exemplary embodiment. FIG. 13 shows a cross-sectional view along line V-V′ of FIG. 12.

Referring to FIG. 12 and FIG. 13, a solar cell 3 is substantially the same as the solar cell 1 of FIG. 1 and FIG. 2, except for a back surface field layer 700. Therefore, detailed description of same elements will not be repeated.

The solar cell 3 may include the base substrate 10, the first passivation layer 200, the first capping layer 300, the back surface field layer 700, the first electrode 610, and the second electrode 620. For example, the back surface field layer 700 may be formed between, e.g., directly between the second surface 12 of the base substrate 10 and the second electrode 620.

The back surface field layer 700 may be formed on the second surface 12 of the p-type semiconductor layer 102. For example, the back surface field layer 700 may be an aluminum-back surface field layer 700 formed by diffusion of an aluminum paste. The back surface field layer 700 may be formed with a p+ area, and it prevents the electrons of the p-type semiconductor layer 102 from being moved to the second surface 12 of the base substrate 10 and being recombined. Accordingly, recombination speed of the electrons and the holes on the rear side may be reduced.

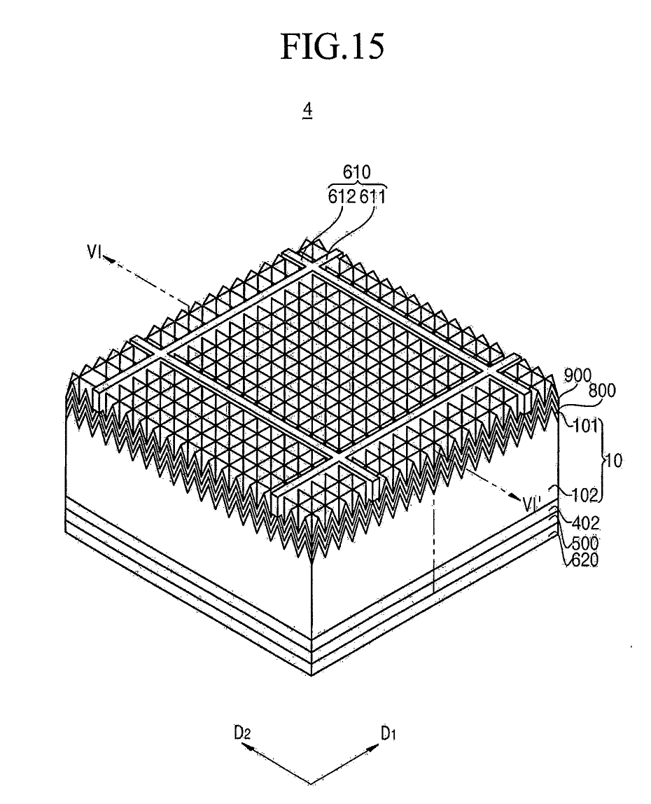

FIG. 14A to FIG. 14B show cross-sectional views of stages in a method of manufacturing the solar cell 3. The method for manufacturing the solar cell 3 includes the same stages described with reference to FIGS. 5A-5D, and therefore, description of same stages will not be repeated.

Referring to FIG. 14A, after the stage of FIG. 5D, i.e., after forming the first passivation layer 200 on the n-type semiconductor layer 101, the first capping layer 300 may be formed. Next, a first electrode paste 61 may be partially formed on the first capping layer 300, and a second electrode paste 62 may be formed on the second surface 12 of the p-type semiconductor layer 102. The first electrode paste 61 may be formed to include a plurality of bus lines expanded in the first direction D1 and formed in the second direction D2 that is substantially perpendicular to the first direction D1, and a finger line expanded in the second direction D2 and formed in the second direction D2 that is substantially perpendicular to the first direction D1, but is not limited thereto.

Referring to FIG. 14B, the first and second electrode pastes 61 and 62 may undergo a co-firing process to form first and second electrodes 610 and 620, and the back surface field layer 700. Upon having undergone the co-firing process, the first electrode paste 61 formed on the first capping layer 300 passes through the first capping layer 300 and the first passivation layer 200 to form the first electrode 610.

The second electrode paste 62 may include aluminum, so the aluminum of the second metal paste 62 formed on the second surface 12 of the base substrate 10 may diffuse from the second surface 12 of the base substrate 10 to form the back surface field layer 700. That is, the aluminum is diffused to a predetermined area from the second surface 12 of the base substrate 10, so the predetermined area is formed to be the back surface field layer 700. Also, the second metal paste 62 becomes the second electrode 620. As such, the co-firing may simultaneously form the second electrode 620 and the back surface field layer 700.

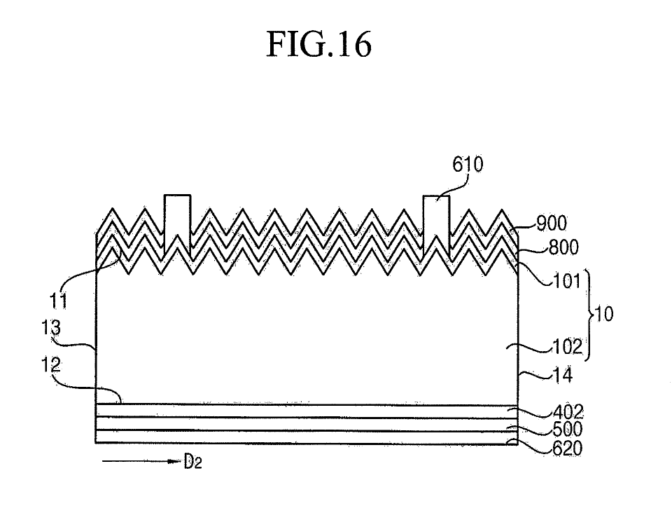

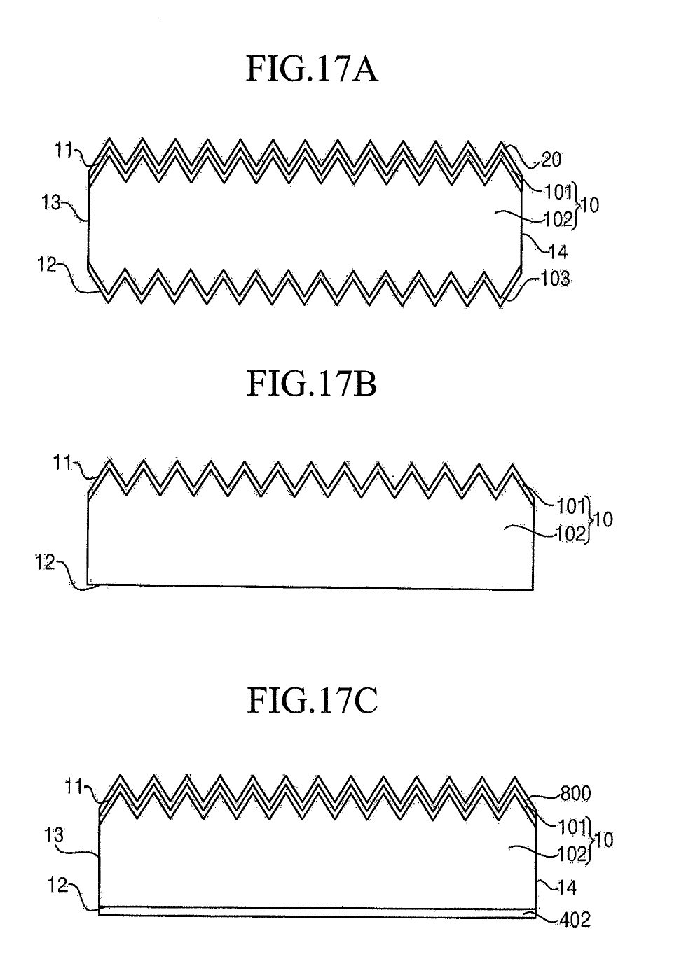

FIG. 15 shows a perspective view of a solar cell according to another exemplary embodiment. FIG. 16 shows a cross-sectional view along line VI-VI′ of FIG. 15.

Referring to FIG. 15 and FIG. 16, a solar cell 4 may include the base substrate 10, a first passivation layer 800, a first capping layer 900, a second passivation layer 402, the second capping layer 500, the first electrode 610, and the second electrode 620.

The solar cell 4 is substantially the same as the solar cell 1 shown in FIG. 1 and FIG. 2, except for the first passivation layer 800, the first capping layer 900, and the second passivation layer 402. Therefore, detailed description of elements described with reference to the solar cell 1 in FIG. 1 and FIG. 2 will not be repeated.

The first passivation layer 800 may be formed on the first surface 11 of the base substrate 10. The first passivation layer 800 may include aluminum oxide (AlOₓ), which is a negative charge oxide film. The first passivation layer 800 may have a negative charge, so it may have a characteristic of pushing the electrons included in the p-type semiconductor layer 102. Therefore, recombination of the electrons of the n-type semiconductor layer 101 and the holes of the p-type semiconductor layer 102 may be prevented. The first passivation layer 800 may be formed by using LPCVD or PECVD.

The first capping layer 900 may be formed on the first passivation layer 800. The first capping layer 900 protects the first passivation layer 800 from an external impact that may occur during the manufacturing process, and functions as an antireflection film for preventing external sunlight from being reflected. The first capping layer 900 may include silicon nitride (SiNₓ). The first capping layer 900 can be formed by using LPCVD or PECVD.

The second passivation layer 402 may be formed below the base substrate 10, and may include aluminum oxide (AlOₓ), which is a negative charge oxide film. The second passivation layer 402 may have a negative charge to have the characteristic of pushing the electrons included in the n-type semiconductor layer 101. Therefore, recombination of the electrons of the n-type semiconductor layer 101 and the holes of the p-type semiconductor layer 102 is prevented. The second passivation layer 402 may be formed by using LPCVD or PECVD. The second capping layer 500 may be formed below the second passivation layer 402. The second capping layer 500 covers the second surface 12 of the solar cell 4 to prevent problems during manufacturing thereof.

The first electrode 610 may be formed on a part of the first capping layer 900. The second electrode 620 may be formed on the entire second capping layer 500.

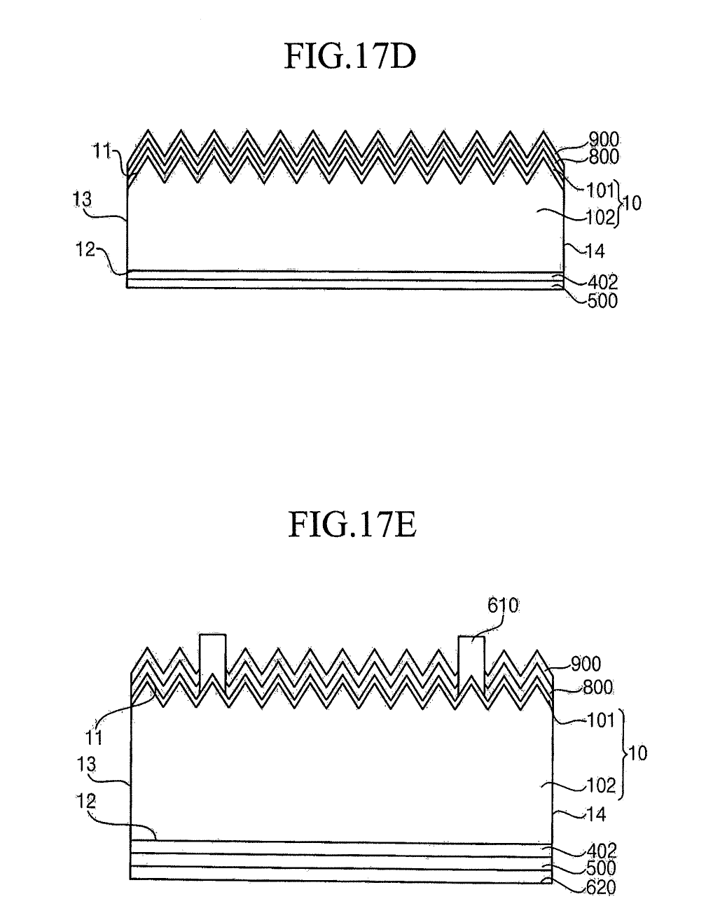

FIG. 17A to FIG. 17E show cross-sectional views of stages in a method for manufacturing the solar cell 4. The stages in FIGS. 17A-17E follow the stage in FIG. 5B.

Referring to FIG. 17A, a protection layer 20 may be formed on the first surface 11 of the base substrate 10. The protection layer 20 is used as an etching preventing film for preventing the n-type semiconductor layer 101 formed on the first surface 11 from being wet etched and removed in the stage for removing the n-type semiconductor layer 120 formed on the second surface 12 of the base substrate 10. The protection layer 20 may be formed of silicon nitride (SiNₓ). The first protection layer 20 may be deposited by the PECVD method. Further, an n-type semiconductor layer 103 may be formed on the second surface 12.

Referring to FIG. 17B, the protruded and depressed pattern and the n-type semiconductor layer 103 may be removed from the second surface 12, and the first protection layer 20 may be removed from the first surface 11. The removal from the first and second surfaces 11 and 12 may be performed through wet etching. The wet etching of the protruded and depressed pattern and the n-type semiconductor layer 103 may be performed by exposing the base substrate 10 to an alkali solution. In this case, the protruded and depressed pattern on the first surface 11 is not etched because of the protection layer 20 formed on the first surface 11. Potassium hydroxide (KOH), sodium hydroxide (NaOH), and tetramethyl ammonium hydroxide (TMAH) are usable for the alkali solution.

Hence, the n-type semiconductor layer 101 formed when the phosphorous (P) is diffused with a constant thickness on the first surface 11 of the base substrate 10 and the p-type semiconductor layer 102 where the phosphorous (P) is not diffused in the direction of the second surface 12 of the base substrate 10 remain. Therefore, the n-type semiconductor layer 101 and the p-type semiconductor layer 102 are bonded. The n-type semiconductor layer 101 defines the first surface 11, and the p-type semiconductor layer 102 defines formed on the second surface 12.

After the protruded and depressed pattern and the n-type semiconductor layer 103 are removed from the second surface 12, the protection layer 20 may be removed by using a hydrofluoric acid (HF) solution through the wet etching process. In general, when the protruded and depressed pattern and the n-type semiconductor layer are removed from the second surface, a protection layer on a first passivation layer may be partially etched or transformed by the influence of a chemical solution. Therefore, when the protection layer is not removed but is formed to be the first passivation layer, the first passivation layer may be transformed or its surface may cause an imbalance. Therefore, according to example, embodiments, an additional process provides removal of the protection layer 20 and individually forming the first passivation layer 200, thereby solving the above-noted problem.

Referring to FIG. 17C, the first passivation layer 800 may be formed on the first surface 11, and the second passivation layer 402 may be formed on the second surface 12. The first passivation layer 800 and the second passivation layer 402 may be formed of the same material and may include aluminum oxide (AlOₓ). The first and second passivation layers 800 and 402 may be formed by using LPCVD or PECVD. The first and second passivation layers 800 and 402 prevent the electrons of the n-type semiconductor layer 101 and the holes of the p-type semiconductor layer 102 from being recombined.

Referring to FIG. 17D, the first capping layer 900 may be formed on the first passivation layer 800, and the second capping layer 500 may be formed on the second passivation layer 402. The first capping layer 900 protects the first passivation layer 800 from an external impact that may occur during the manufacturing process, and also functions as an antireflection film for preventing sunlight from being reflected. The second capping layer 500 covers the second surface 12 of the solar cell 4 to prevent a problem that may be generated when the solar cell 4 is manufactured. The first and second capping layers 900 and 500 may include silicon nitride (SiNₓ).

The silicon nitride (SiNₓ) may include hydrogen. However, when heat is applied, the silicon nitride (SiNₓ) including hydrogen may discharge hydrogen to generate blistering, e.g., air bubbles, at an edge of the first and second passivation layers 800 and 402. Therefore, the silicon nitride (SiNₓ) may include a small amount of hydrogen. For example, when the first and second passivation layers 800 and 402 are formed by PECVD, the silicon nitride (SiN_{X}) may include about 8 atom % to about 15 atom % of hydrogen, and when the first and second passivation layers 800 and 402 are formed by LPCVD, the silicon nitride (SiN_{X}) may include little or no hydrogen.

The first and second passivation layers 800 and 402 may be formed by depositing high-density silicon nitride (SiNₓ) using LPCVD or PECVD. When low-density silicon nitride (SiNₓ) is deposited, the co-firing process performed to form an electrode may generate a punch-through problem that is formed when a metal layer is passed through the silicon nitride (SiNₓ). When high-density silicon nitride (SiNₓ) is deposited, it becomes difficult for the metal layer to pass through the silicon nitride (SiNₓ) so the above-noted problem is solved.

In general, when a second capping layer is formed on a second passivation layer, i.e., after the second passivation layer in provided in the air for a predetermined time before the second capping layer is deposited, an impurity, e.g., moisture, may be generated between the second passivation layer and the second capping layer. As such, an annealing process may be included so as to remove the impurity. In example embodiments, however, the annealing process may be omitted since the second passivation layer 402 is exposed to the air for only a short time. Accordingly, omission of the annealing process simplifies the manufacturing process, and problems, e.g., punch-through or blistering, that may occur during the manufacturing process may be solved without an additional process.

Referring to FIG. 6, FIG. 8, FIG. 17C, and FIG. 17D, the first and second passivation layers 800 and 402 and the first and second capping layers 900 and 500 may be formed by the deposition device shown in FIG. 6 and FIG. 8. That is, assuming that the base substrate 10 including the n-type semiconductor layer 101 and the p-type semiconductor layer 102 is the mother substrate (W), the mother substrate (W) moves in the third direction D3. The second mother substrate (W) passes through the load chamber (LC) and the first buffer chamber BC1 to reach the process chamber PC1. The first passivation layer 800 may be formed on the first surface 11 according to the top down sequence by the first processor PC11 of the process chamber PC1, and the second passivation layer 402 is formed on the second surface 12 according to the bottom up sequence by the second processor PC12. The mother substrate (W) on which the first and second passivation layers 800 and 402 are formed may be passed through the second buffer chamber BC2 and the unload chamber (ULC) to be detached from the device.

Also, the mother substrate (W) on which the first and second passivation layers 800 and 402 are formed undergoes the above-noted process so the first capping layer 900 may be formed on the first passivation layer 800 by the first processor PC11, and the second capping layer 500 is formed on the second passivation layer 400 as a sequential process.

Further, the first and second passivation layers 800 and 402 and the first and second capping layers 900 and 500 may be deposited by the deposition device of FIG. 8. The deposition process is substantially equivalent to that of FIG. 6.

Referring to FIG. 17E, the first electrode 610 may be formed on a part of the first capping layer 900. A first metal paste may be partially formed on the first capping layer 900. The first metal layer can include a plurality of bus lines extended in a first direction D1 and formed in a second direction D2 that is substantially perpendicular to the first direction D1 and a finger line extended in the second direction D2 and formed in the first direction D1. The first metal layer undergoes the co-firing process to pass through the first passivation layer 800 and the first capping layer 900 and form the first electrode 610, and is electrically connected to the p-type semiconductor layer 102.

The second electrode 620 may be formed below the second capping layer 500. The second passivation layer 402 and the second capping layer 500 may be partially etched by using the laser beams, and a second metal paste is formed on the second capping layer, the second passivation layer 402, and the base substrate 10 from which the second capping layer 500 is removed and which is exposed. The first and second metal pastes may form the first and second electrodes 610 and 620 through the co-firing process. The first electrode 610 passes through the first capping layer 900 and the first passivation layer 800 and is electrically connected to the base substrate 10. The second electrode can form the second electrode 620 without undergoing the co-firing process while melting the second metal layer by using laser beams. The second electrode 620 may be formed on the second surface 12 of the exposed base substrate 10 and the second capping layer 500. Therefore, the second electrode 620 may be electrically connected to the p-type semiconductor layer 102.

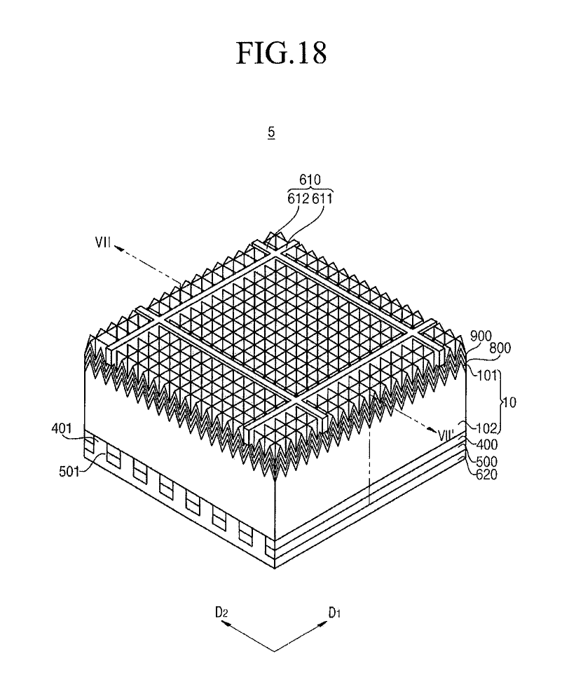

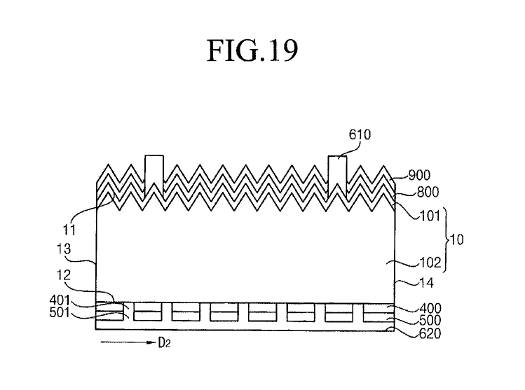

FIG. 18 shows a perspective view of a solar cell according to another exemplary embodiment. FIG. 19 shows a cross-sectional view along line VII-V11″ of FIG. 18.

A solar cell 5 in FIGS. 18-19 is substantially the same as the solar cell 4 in FIGS. 15-17E, except for the contact holes 401 and 501 formed on the second passivation layer 402 and the second capping layer 500, respectively. The solar cell 5 may include the base substrate 10, the first passivation layer 800, the first capping layer 900, the first electrode 610, the second electrode 620, the second passivation layer 402 including a contact hole 401, and the second capping layer 500 including a contact hole 501.

The second passivation layer 402 and the second capping layer 500 may be formed between the p-type semiconductor layer 102 and the second electrode 620, and may include a plurality of contact holes 401 and 501. The second electrode 620 may be electrically connected to the p-type semiconductor layer 102.

The method for manufacturing the solar cell 5 is substantially equivalent to the method for manufacturing the solar cell 4 shown in FIG. 16. However, the contact holes 401 and 501 may be formed on the second passivation layer 402 and the second capping layer 500 by using the laser edge paste or photolithography.

According to the above detailed description, the electron-hole recombination speed is reduced by forming a capping layer on a passivation layer including hydrogen, and reflection of sunlight is reduced because of the double antireflection film, i.e., sequentially formed a passivation layer and a capping layer, thereby providing a high-efficiency solar cell. Both layers of the base substrate with the same material may be simultaneously formed to simplify the manufacturing process, the base substrate may be deposited without flipping to reduce the time for depositing the layer, i.e., reducing the turnaround time, the time for the layer formed in the inner part to be exposed in the air is reduced to omit additional processes, e.g., eliminate annealing that may cause punch through and blistering.

In contrast, in a conventional solar cell including a bonded structure of a p-type semiconductor layer and an n-type semiconductor layer, a fast recombination speed of electrons and holes reduces efficiency of the solar cell. Further, when a conventional passivation layer is formed on both sides of a solar cell without a capping layer, a plurality of additional processes may be required in order to prevent transformation of the passivation layers during formation thereof. In addition, attempts to form passivation layers and capping layers on both sides of the conventional solar cell required flipping a wafer to allow deposition on both sides thereof, thereby increasing manufacturing time due to the turnaround time required to deposit both sides.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a base substrate including a first surface and a second surface opposite the first surface, the base substrate being configured to have sunlight incident on the first surface;
a doping layer on the first surface of the base substrate;
a first passivation layer on the doping layer, the first passivation layer including hydrogen;
a first capping layer on the first passivation layer, the first capping layer being configured to prevent discharge of hydrogen from the first passivation layer;
a first electrode on the first capping layer; and
a second electrode on the second surface of the base substrate.

2. The solar cell as claimed in claim 1, wherein the first passivation layer includes at least one of silicon nitride (SiNₓ), silicon oxide (SiOₓ), and silicon oxynitride (SiON).

3. The solar cell as claimed in claim 1, wherein the first capping layer includes at least one of silicon nitride (SiNₓ), silicon oxynitride (SiON), aluminum nitride (AlN), aluminum oxide (AlOₓ), a carbon thin film, cerium oxide (CeOₓ), and titanium oxide (TiOₓ).

4. The solar cell as claimed in claim 1, wherein the first capping layer has a thickness of about 5 nm to about 30 nm.

5. The solar cell as claimed in claim 1, further comprising:
a second passivation layer on the second surface of the base substrate; and
a second capping layer on the second passivation layer, the second electrode being on the second capping layer.

6. The solar cell as claimed in claim 1, further comprising a back surface field (BSF) layer on the second surface of the base substrate, the BSG layer including aluminum (Al) paste, and the second electrode being on the BSF layer.

7. A solar cell, comprising:
a base substrate including a first surface and a second surface opposite the first surface, the base substrate being configured to have sunlight incident on the first surface;
a doping layer on the first surface of the base substrate;
first and second passivation layers on the doping layer and on the second surface of the base substrate, respectively, each of the first and second passivation layers including a negative charge oxide film;
first and second capping layers on respective first and second passivation layers; and
first and second electrodes on respective first and second capping layers.

8. The solar cell as claimed in claim 7, wherein the first and second passivation layers include aluminum oxide (AlOₓ).

9. The solar cell as claimed in claim 7, wherein the first and second capping layers include silicon nitride (SiNₓ).

10. A method for manufacturing a solar cell, the method comprising:
forming a doping layer on a first surface of a base substrate to have sunlight incident thereon;
forming a first passivation layer on the doping layer, the first passivation layer including hydrogen;
forming a first capping layer on the first passivation layer, such that the first capping layer is configured to prevent discharge of hydrogen from the first passivation layer;
forming a first electrode on the first capping layer; and
forming a second electrode on a second surface of the base substrate, the second surface being opposite the first surface.

11. The method as claimed in claim 10, wherein forming the first passivation layer includes performing a plasma enhanced chemical vapor deposition method.

12. The method as claimed in claim 10, further comprising:
forming a second passivation layer on the second surface of the base substrate; and
forming a second capping layer on the second passivation layer.

13. The method as claimed in claim 12, wherein the first capping layer and the second passivation layer are formed simultaneously of the same material.

14. The method as claimed in claim 13, wherein forming the first capping layer on the first passivation layer and forming the second passivation layer on the second surface of the base substrate includes:
providing the base substrate to a loader;
providing the base substrate to a first processor connected to a first buffer, after passing through the first buffer connected to the loader;
depositing the second passivation layer on the second surface of the base substrate by the first processor;
depositing the first capping layer on the first passivation layer by a second processor adjacent the first processor;
providing the base substrate to an unloader by passing the same through a second buffer connected to the second processor; and
detaching the base substrate by the unloader.

15. The method as claimed in claim 14, wherein the first and second processors are formed in respective first and second chambers, the first and second chambers being formed to be connected with each other in an open gate form or being formed in a single chamber.

16. The method as claimed in claim 10, further comprising forming a back surface field layer on the second surface of the base substrate, forming the back surface field layer on the second surface of the base substrate including:
forming an aluminum paste on the second surface of the base substrate; and
applying heat to the aluminum paste, such that aluminum diffuses to the second surface of the base substrate.

17. A method for manufacturing a solar cell, the method comprising:
forming a doping layer on a first surface of a base substrate, such that sunlight is incident on the first surface, and the second surface is opposite the first surface;
forming first and second passivation layers on the doping layer and on the second surface of the base substrate, respectively, each of the first and second passivation layers including a negative charge oxide film;
forming first and second capping layers on the first and second passivation layers, respectively; and
forming first and second electrodes on the first and second capping layers, respectively.

18. The method as claimed in claim 17, wherein forming the first and second passivation layers is performed simultaneously, and forming the first and second capping layers is performed simultaneously.

19. The method as claimed in claim 17, wherein forming the first and second capping layers includes performing a low pressure chemical vapor deposition method.

20. The method as claimed in claim 17, wherein forming the first and second passivation layers includes:
providing the base substrate to a loader;
providing the base substrate to a first processor connected to a first buffer, after passing through the first buffer connected to the loader;
depositing the first passivation layer on the doping layer of the base substrate by the first processor;
depositing the second passivation layer on the second surface of the base substrate by a second processor adjacent the first processor;
providing the base substrate to an unloader after passing through a second buffer connected to the second processor; and
detaching the base substrate by the unloader.

21. The method as claimed in claim 20, wherein forming the first and second capping layers includes:
providing the base substrate to the loader;
providing the base substrate to the first processor after passing through the first buffer;
forming the first capping layer on the first passivation layer of the base substrate by the first processor;
depositing the second capping layer on the second passivation layer of the base substrate by the second processor;
providing the base substrate to the unloader after passing through the second buffer; and
detaching the base substrate by the unloader.

22. The method as claimed in claim 21, wherein the first and second processors are formed in respective first and second chambers, the first and second chambers being formed to be connected with each other in an open gate form or being formed in a single chamber.

23. A deposition device, comprising:
a loader configured to load a wafer having a first surface and a second surface opposite the first surface, the wafer having a doping layer on the first surface;
a first buffer connected to the loader and configured to move the wafer;
a first processor connected to the first buffer and configured to deposit a material on the first surface of the wafer;
a second processor adjacent the first processor and configured to deposit a material on the second surface of the wafer;
a second buffer connected to the second processor and configured to move the wafer; and
an unloader connected to the second buffer and configured to unload the wafer.

24. The deposition device as claimed in claim 23, wherein the first processor and the second processor are configured to deposit the material without standing-by exposure.

25. The deposition device as claimed in claim 23, wherein the first and second processors are configured to deposit dielectric on the first and second surfaces, the dielectric layers being capping layers including aluminum oxide (AlOₓ), aluminum nitride (AlN), silicon oxide (SiOₓ), silicon nitride (SiNₓ), or silicon oxynitride (SiON), and/or being passivation layers including silicon nitride (SiNₓ), carbon thin films, aluminum nitride (AlN), silicon oxynitride (SiON), silicon carbide (SiC), or silicon carbonitride (SiCN).

26. The deposition device as claimed in claim 23, wherein the first processor is in a first chamber, the second processor is in a second chamber, and a surface of the first chamber and a surface of the second chamber are connected with each other in an open gate form.

27. The deposition device as claimed in claim 23, wherein the first processor and the second processor are in a same chamber.
